(19) United States
(12) Patent Application Publication
(10) Pub. No.: US 2008/0006847 A1
(43) Pub. Date: Jan. 10, 2008

(54) Semiconductor protective structure for electrostatic discharge

(76) Inventors: Peter Grombach, Heilbronn (DE); Andre Heid, Marbach (DE); Manfred Klaussner, Heilbronn (DE); Stefan Schwantes, Heilbronn (DE)

Correspondence Address: MCGRATH, GEISSLER, OLDS & RICHARDSON, PLLC, P.O. BOX 1364, FAIRFAX, VA, 22038-1364, US

(21) Appl. No.: 11/812,637

(22) Filed: Jun. 20, 2007

Related U.S. Application Data
(60) Provisional application No. 60/831,232, filed on Jul. 17, 2006.

(30) Foreign Application Priority Data
Jun. 20, 2006 (DE) DE102006028721

(51) Int. Cl. H01L 31/00; H01L 29/739

(52) U.S. Cl. 257/197

(57) ABSTRACT

A semiconductor protective structure suitable for electrostatic discharge with a field-effect transistor, whose source forms an emitter, whose body forms a base, and whose drain forms a collector of a bipolar transistor. A plurality of drain regions are formed within a body region of the field-effect transistor, and the drain regions are connected to one another by a conductor.

This nonprovisional application claims priority to German Patent Application No. DE 102006028721, which was filed in Germany on Jun. 20, 2006, and to U.S. Provisional Application No. 60/831,232, which was filed on Jul. 17, 2006, and which are both herein incorporated by reference.

### BACKGROUND OF THE INVENTION

1. Field of the Invention

The present invention relates to a semiconductor protective structure that is suitable for electrostatic discharge (ESD).

2. Description of the Background Art

U.S. Pat. No. 6,873,505 B2 discloses a semiconductor component that has electrostatic discharge protective circuitry, which is connected to a common discharge line (CDL). In an embodiment of U.S. Pat. No. 6,873,505 B2, the semiconductor component comprises a plurality of bond pads, each of which is assigned a protection circuit. For protection, a controlled semiconductor rectifier (SCR) comprising a pnp bipolar transistor and an npn bipolar transistor, is provided whose triggering voltage is reduced by a Zener diode as the triggering element. Typical for ESD protection circuits is the so-called snapback effect. In this case, the voltage rises initially significantly starting from zero. If sufficient charge carriers are generated, the voltage declines despite a further increasing current through the protection circuit.

### SUMMARY OF THE INVENTION

It is therefore an object of the present invention to provide a semiconductor protective structure for electrostatic discharge, particularly with respect to reduction of the snapback voltage.

Accordingly, a semiconductor protective structure is provided that is suitable for electrostatic discharge. The semiconductor protective structure has a field-effect transistor. Semiconductor regions of the field-effect transistor simultaneously form semiconductor regions of a parasitic bipolar transistor. The source of the field-effect transistor forms an emitter of the bipolar transistor. The body of the field-effect transistor forms a base of the bipolar transistor. The drain of the field-effect transistor forms a collector of the bipolar transistor. The body is here designed preferably as a well, whereby in the well the source and the drain are formed, for example, by introduced, particularly implanted, dopants.

A plurality of drain regions is formed within a body region of a single field-effect transistor. A plurality of drain regions is hereby two or more than two drain regions. These drain regions in this case are formed with dopants of the same conductivity type. For example, the body region is p-doped and the drain regions are formed by n+ doping. The drain regions are connected to one another by a conductor. This conductor can have, for example, a metallization, a silicide, or a particularly highly doped compound of polycrystalline silicon. Each drain region has a separate PN junction to the body region, whereby a space charge region (RLZ) forms along said PN junction.

An embodiment provides that a first drain region and a second drain region of the plurality of drain regions are spaced from one another in the direction of a gate length of the field-effect transistor. Therefore, the first drain region is disposed closer than the second drain region to the gate electrode. Advantageously, moreover, a third drain region and optionally a fourth drain region of the plurality of drain regions are provided, which are also formed spaced from one another in the direction of the gate length of the field-effect transistor and to the first drain region and the second drain region.

According to another embodiment of the invention, it is provided that the first drain region is formed between a gate electrode and the second drain region. Advantageously, a conductive transition region is formed between the conductor and the first drain region closer to the second drain region than to the gate electrode. This achieves that the first drain region is formed as a small resistor that causes uniform current distribution. In this case, the first drain region can have a dopant distribution adapted to the resistor.

Another embodiment provides that at least two drain regions of the plurality of drain regions are spaced from one another in the direction of a gate width of the field-effect transistor. These two drain regions as well are connected conductively to one another via the conductor, in particular short-circuited. The direction of the gate width is usually perpendicular to the direction of the gate length.

It can also be provided that the plurality of drain regions can be formed in a grid within the body region. The grid is preferably two-dimensional, so that a matrix of columns and lines of drain regions is formed. A three-dimensional grid is also possible. It is also possible to form a plurality of drain regions at different layer depths in the semiconductor material of the semiconductor protective structure.

According to another aspect of the invention, it is provided that the field-effect transistor can be formed as a closed structure. For an NMOS field-effect transistor, a body terminal region of the body is preferably formed in the outer area of the closed structure and the drain regions in the inner area of the closed structure. According to an advantageous embodiment, it is provided that a pn junction between the body and source goes completely around the closed structure.

In an embodiment, the closed structure is ring-shaped or oval. These structures make it possible to place the critical terminal for electrostatic discharge, for example, the cathode terminal of the semiconductor protective structure in the case of an NMOS field-effect transistor or parasitic npn bipolar transistor, in the inner region of the semiconductor protective structure and the anode terminal in the outer region of the semiconductor protective structure. Furthermore, edge effects at interfaces, particularly to dielectrics, are reduced or are even completely prevented by the closed structure.

Preferably, a fixed potential is applied to a gate electrode of the field-effect transistor in such a way that no conduction channel forms below the gate electrode. In this case, the field-effect transistor blocks. There are various options for applying a fixed potential to the gate electrode. According to a preferred embodiment of the invention, a gate electrode of the field-effect transistor is connected conductively to the source and/or the body. For example, a body terminal region, a source region, and the gate electrode are short-circuited across a metallization (ggMOS).

In order to prevent a so-called latch-up effect, an embodiment provides that the field-effect transistor is isolated by a buried dielectric in the vertical direction and by a dielectric-filled trench structure in the lateral direction. (Box) These isolation structures are used for isolation from a substrate and/or from a neighboring semiconductor structure, such as for example, a field-effect transistor.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic sectional view of a part of a semiconductor protective structure that is suitable for electrostatic discharge,

FIG. 2 is a schematic top plan view of a part of a semiconductor protective structure of a first exemplary embodiment,

FIG. 3 is a schematic top plan view of a part of a semiconductor protective structure of a second exemplary embodiment,

FIG. 4 is a schematic top plan view of a part of a semiconductor protective structure of a third exemplary embodiment, and

FIGS. 5a and 5b are schematic top plan views of combinations of a plurality of parts of a closed semiconductor protective structure.

### DETAILED DESCRIPTION

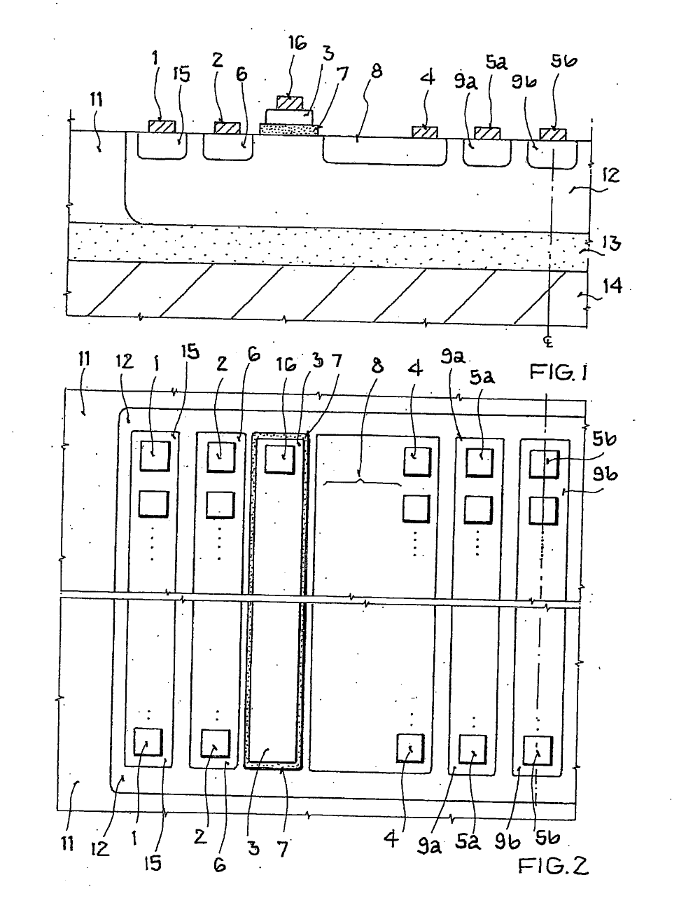

FIG. 1 shows a schematic sectional view through a chip with a semiconductor protective structure. This is suitable for electrostatic discharges and is also called an ESD structure (ESD=electrostatic discharge). This semiconductor protective structure is connected to terminals of an integrated circuit that is to be protected from electrostatic discharges by the semiconductor protective structure. Electrostatic discharges can also act via terminals of the integrated circuit. For protection, the semiconductor protective structure is also connected to these terminals. Advantageously, the semiconductor protective structure is integrated together with the integrated circuit to be protected on a chip and is produced in the same manufacturing process.

The semiconductor protective structure has a field-effect transistor with a source, a drain, a gate, and a body. The body can also be called a bulk. In FIG. 1, a body region 12 is shown, which in the exemplary embodiment of an NMOS field-effect transistor is p-doped. A higher p-doped body terminal region 15 is connected by means of a body metallization 1. A gate oxide 7 with a gate electrode 3 is disposed in a subregion of body region 12. Gate electrode 3 is connected by a gate metallization 16.

The field-effect transistor of FIG. 1 is operated as an ESD structure exclusively in the blocked state. For this purpose, a potential that prevents the formation of a channel in the subregion below gate oxide 7 is applied to the gate electrode. For this purpose, the gate metallization and the body metallization are short-circuited, for example (not shown in FIG. 1). Furthermore, a source region 6 is formed between body terminal region 15 and gate oxide 7 in body region 12, for example, by implantation of an n-conducting dopant. Source region 6 is also short-circuited by a metallization (not shown in FIG. 1) with body terminal region 15 and gate electrode 16.

Furthermore, in the sectional view of the exemplary embodiment of FIG. 1, a first drain region 8, a second drain region 9a, and a third drain region 9b are formed by implantation of an n-conducting dopant. All drain regions are therefore n-conducting. First drain region 8 is connected by a first drain metallization 4, second drain region 9a by a second drain metallization 5a, and third drain region 9b by a third drain metallization 5b. All drain regions 8, 9a, 9b are short-circuited by a metal conductor made as a metallization (not shown in FIG. 1). They are therefore at the same potential.

In the case of an electrostatic discharge, a voltage is generated between drain terminals 4, 5a and 5b and body terminal 1. This voltage causes an electric field in a space charge region along each PN junction formed by the respective drain region 8, 9a, 9b and body region 12. Each drain region 8, 9a, 9b with body region 12 consequently forms a unique drain-body diode. The field strength is highest within a region of the space charge region of the respective drain region 8, 9a, 9b that faces body terminal region 15. Because of the very great field strength in this region, the greatest number of charge carriers is also generated in this region. The three drain regions 8, 9a, 9b each have this type of region, so that the charge carrier generation as a total by these three drain regions 8, 9a, 9b is greater than in a single drain region.

The greater the charge carrier generation, the greater the current flowing in body terminal region 15. This current generates a voltage drop in body region 12 and body terminal region 15, so that the PN junction between body region 12 and source region 6 is operated in the flow direction (>0.7 V). As a result, the bipolar transistor switches on due to the positive base-emitter voltage. The charge can be discharged through the collector-emitter path of the switched on bipolar transistor. Therefore, the so-called snapback voltage can be considerably reduced by this means.

First drain region 8 has a length extending in the direction of a gate length. First drain terminal 4 is thereby placed in first drain region 8 at a distance from gate electrode 16. This has the effect that drain region 8 acts as a small resistor for the current flow in the direction of body terminal region 15. The small resistor in turn causes uniform distribution of the current generated by the generation of charge carriers. Local current overshoots are reduced or totally avoided in this way.

A dielectric 13 isolates body region 12 of the field-effect transistor from a semiconductor substrate 14, so that a so-called SOI structure (semiconductor on insulator) is formed. Furthermore, the semiconductor protective structure is isolated by isolating dielectric-filled trench structure 11 from one or more neighboring semiconductor structures. Moreover, the semiconductor regions 12, 15, 6, 8, 9a, 9b, adjacent to the surface, can be covered by a layer of boron-phosphorus-silicate glass (BPSG) for isolation.

FIG. 2 shows a schematic top plan view of a part of a semiconductor protective structure of an exemplary embodiment corresponding to FIG. 1. Body terminal region 15, source region 6, gate electrode 3, and drain regions 8, 9a, and 9b extend uninterrupted in the longitudinal direction lengthwise in the direction of a gate width. Along this lengthwise extension, each region 15, 6, 8, 9a, 9b and gate electrode 3 in each case have a plurality of metal contacts 1, 2, 16, 4, 5a, 5b. In this case, all metal contacts 1, 2, 16 of the body, source, and gate electrode are short-circuited (not shown in FIG. 2). All metal contacts 4, 5a, 5b of drain regions 8, 9a, 9b are also short-circuited by a metallic conductor (also not shown in FIG. 2). Trench structure 11 filled with dielectric completely surrounds the field-effect transistor of the semiconductor protective structure.

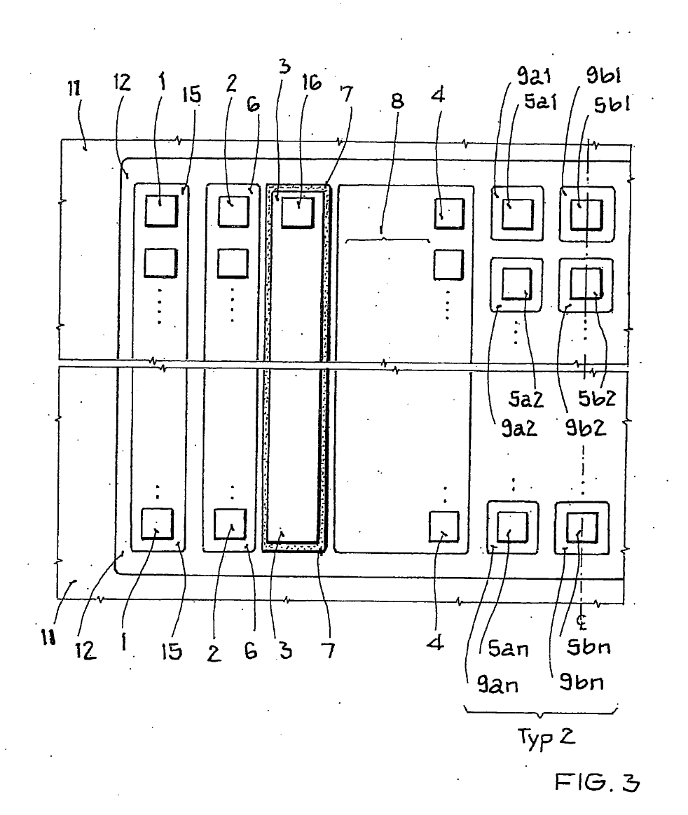

FIG. 3 shows an exemplary embodiment, alternative to FIG. 2, which can also be combined in a semiconductor protective structure with the exemplary embodiment of FIG. 2. Drain region 8 is unchanged. However, a plurality of additional drain regions 9a1 to 9an and 9b1 to 9bn are now provided. These drain regions 9a1 to 9an and 9b1 to 9bn are thereby arranged in the grid. In this case, the grid forms a matrix with two columns and n lines. Drain regions 9a1 to 9an and 9b1 to 9bn in this case are spaced from one another in the direction of a length of gate electrode 3. Drain regions 9a1 to 9an and 9b1 to 9bn are also spaced from one another in the direction of a width of gate electrode 3. Each of these drain regions 9a1 to 9an and 9b1 to 9bn is separated from another of these drain regions 9a1 to 9an and 9b1 to 9bn by a part of body region 12. All drain regions 9a1 to 9an and 9b1 to 9bn are short-circuited relative to each other by a metal conductor.

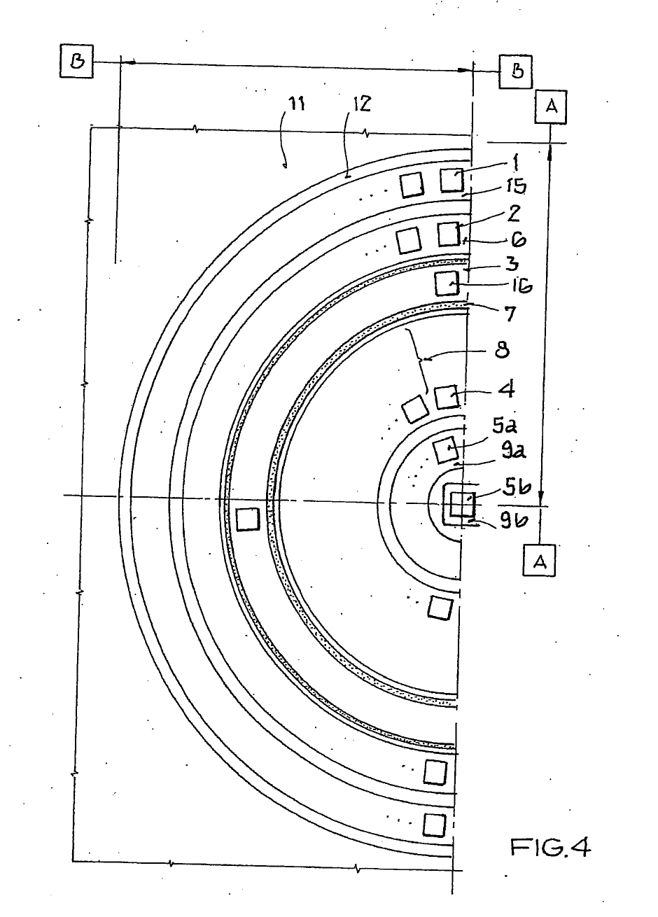

FIG. 4 shows another, also combinable exemplary embodiment of a semiconductor protective structure in a schematic top plan view. A part of a semiconductor protective structure is shown as a semicircle with two quadrant segments A-A, B-B. In this exemplary embodiment drain regions 8, 9a, 9b are formed in the center of the circle. They are surrounded in sequence by gate electrode 3, source region 6, body terminal region 15, and trench structure 11. Alternatively, of course, a grid of drain regions analogous to FIG. 3 can be formed in the interior of the semicircular structure.

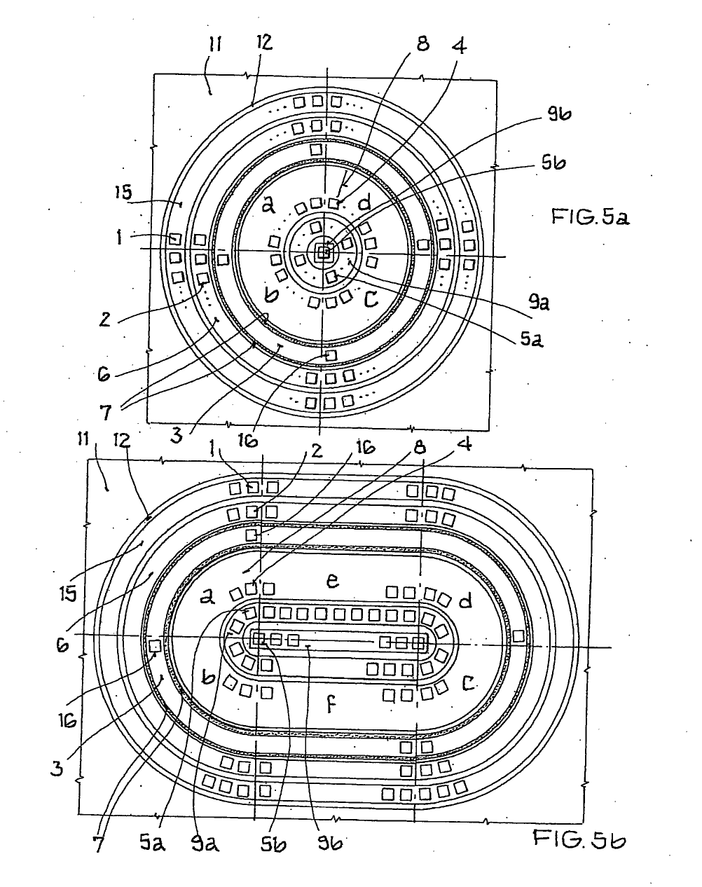

FIGS. 5a and 5b show two exemplary embodiments for a complete semiconductor protective structure in a top plan view, which consists of partial views of the previously described exemplary embodiments. FIG. 5a shows a closed structure as a circular structure. Each quadrant segment a, b, c or d corresponds thereby to a quadrant segment of FIG. 4.

FIG. 5b shows a closed structure as an oval (stadium structure). In this case, the quadrant segments a, b, c and d correspond to a quadrant segment of FIG. 4. The segments e and f in this case correspond to a lengthwise extension of the structure analogous to FIG. 2 or FIG. 3. In this case, drain regions 8, 9a, 9b are formed in the middle of the oval structure.

FIGS. 5a and 5b have the advantage that no edge regions are present in which interfaces, for example, another PN junction, could interfere with the operating mode of the component. Moreover, these structures are integrated with saving of space.

The invention is not limited to the shown exemplary embodiments. An alternative embodiment provides, for example, a PMOS field-effect transistor with a parasitic pnp bipolar transistor formed by the PMOS field-effect transistor. The geometric design of the drain regions can also deviate from those depicted in the figures.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A semiconductor protective structure for electrostatic discharge (ESD) comprising:
a field-effect transistor, whose source forms an emitter, whose body forms a base, and whose drain forms a collector of a bipolar transistor; and
a plurality of drain regions having a substantially same conductivity type is formed within a body region of the field-effect transistor,
wherein the drain regions are connected to one another by a conductor.

2. The semiconductor protective structure according to claim 1, wherein a first drain region and a second drain region of the plurality of the drain regions are spaced from one another in a direction of a gate length of the field-effect transistor.

3. The semiconductor protective structure according to claim 2, wherein the first drain region is formed between a gate electrode and the second drain region, and wherein a conductive transition region is formed between the conductor and the first drain region closer to the second drain region than to the gate electrode.

4. The semiconductor protective structure according to claim 1, wherein two drain regions of the plurality of drain regions are spaced from one another in a direction of a gate width of the field-effect transistor.

5. The semiconductor protective structure according to claim 1, wherein the plurality of the drain regions are formed in a grid within the body region.

6. The semiconductor protective structure according to claim 1, wherein the field-effect transistor is formed as a closed structure, wherein a body terminal region of the body is formed in an outer area of the closed structure and the drain regions in an inner area of the closed structure.

7. The semiconductor protective structure according to claim 6, wherein the closed structure is ring-shaped or oval.

8. The semiconductor protective structure according to claim 6, wherein a PN junction between the body region and a source region is formed substantially completely around the closed structure.

9. The semiconductor protective structure according to claim 1, wherein a fixed potential is applied to a gate electrode of the field-effect transistor so that no conduction channel forms below the gate electrode.

10. The semiconductor protective structure according to claim 1, wherein a gate electrode of the field-effect transistor is connected conductively to the source and/or the body.

11. The semiconductor protective structure according to claim 1, wherein the field-effect transistor is isolated by a buried dielectric in a vertical direction and by a dielectric-filled trench structure in a lateral direction.
